(19) United States
(12) Patent Application Publication
(10) Pub. No.: US 2023/0384970 A1
(43) Pub. Date: Nov. 30, 2023

(54) STORAGE DEVICE AND OPERATING METHOD THEREOF

(71) Applicant: SK hynix Inc., Gyeonggi-do (KR)

(72) Inventor: Ji Hoon HWANG, Gyeonggi-do (KR)

(21) Appl. No.: 17/987,131

(22) Filed: Nov. 15, 2022

(30) Foreign Application Priority Data
May 31, 2022 (KR) 10-2022-0066737

(51) Int. Cl. G06F 3/06; G06F 9/4401

(52) U.S. Cl. CPC G06F 3/0658; G06F 3/0611; G06F 3/0679; G06F 9/4411

(57) ABSTRACT

A storage device includes: a memory device including a plurality of memory dies; a calibration controller for performing a calibration operation of measuring first to third calibration values with respect to a data strobe signal at first to third temperatures of the storage device, respectively; a calibration register for generating an equation between a temperature and a calibration value based on the first to third calibration values and the first to third temperatures, and storing a calibration table based on the equation; and a memory interface for communicating with the memory device, based on the calibration table.

### CROSS-REFERENCE TO RELATED APPLICATION

The present application claims priority under 35 U.S.C. § 119(a) to Korean patent application number 10-2022-0066737, filed on May 31, 2022, the entire disclosure of which is incorporated herein by reference.

### BACKGROUND

### Field of Invention

The present disclosure generally relates to an electronic device, and more particularly, to a storage device including a memory device and a memory controller.

### Description of Related Art

A storage device is a device which stores data under the control of a host device such as a computer or a smart phone. The storage device may include a memory device for storing data and a memory controller for controlling the memory device. The memory device is classified into a volatile memory device and a nonvolatile memory device.

The nonvolatile memory device is a memory device in which data does not disappear even when the supply of power is interrupted. The nonvolatile memory device may include a Read Only Memory (ROM), a Programmable ROM (PROM), an Electrically Programmable ROM (EPROM), an Electrically Erasable ROM (EEROM), a flash memory, and the like.

The nonvolatile memory device may receive data or transmit data in synchronization with a timing signal. Specifically, the nonvolatile memory device may transmit/receive data by using a data strobe signal having a constant cycle. For example, the memory device may receive data transmitted from the memory controller, based on the data strobe signal in a write operation. Alternately, the memory device may transmit data to the memory controller, based on the data strobe signal in a read operation. The memory device includes a plurality of dies, and the memory device and the memory controller are connected to each other through a plurality of channels. Therefore, a skew with the data strobe signal may occur due to physical differences between the dies or the channels, and the like. The memory controller may perform a calibration operation on the data strobe signal to correct this skew.

### SUMMARY

Embodiments of the present disclosure provide a storage device for supporting an improved calibration operation on a data strobe signal and an operating method of the storage device.

In accordance with an aspect of the present disclosure, there is provided a storage device including: a memory device including a plurality of memory dies; a calibration controller configured to perform a calibration operation of measuring first to third calibration values with respect to a data strobe signal at first to third temperatures of the storage device, respectively; a calibration register configured to generate an equation between a temperature and a calibration value based on the first to third calibration values and the first to third temperatures, and to store a calibration table based on the equation; and a memory interface configured to communicate with the memory device, based on the calibration table.

In accordance with another aspect of the present disclosure, there is provided a method of operating a storage device, the method including: performing a calibration operation of measuring first to third calibration values with respect to a data strobe signal at first to third temperatures of the storage device, respectively; generating an equation between a temperature and a calibration value, based on the first to third calibration values and the first to third temperatures; storing a calibration table, based on the equation; and communicating with a memory device, based on the calibration table.

In accordance with another aspect of the present disclosure, there is provided a storage device including: a memory controller configured to provide a data strobe signal; and a memory device configured to receive and transmit data from and to the memory controller based on the data strobe signal, wherein the memory controller is configured to perform a DQS calibration operation by: measuring a plurality of data strobe signal (DQS) calibration values at multiple temperatures; determining an estimation model indicating the relationship between DQS calibration values and temperatures based on the measured the DQS calibration values and the measured multiple temperatures; measuring a DQS calibration value at an operation temperature of the storage device; determining a DQS calibration estimation value corresponding to the operation temperature using the estimation model, the DQS calibration estimation value for calibrating the data strobe signal; comparing the DQS calibration value measured at the operation temperature with DQS calibration estimation value; and updating the estimation model based on the comparison result.

### BRIEF DESCRIPTION OF THE DRAWINGS

Various embodiments of the present disclosure will now be described more fully hereinafter with reference to the accompanying drawings; however, the embodiments may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a storage device in accordance with an embodiment of the present disclosure.

FIG. 2 is a diagram illustrating signals exchanged between a memory device and a memory controller in accordance with an embodiment of the present disclosure.

FIG. 3 is a diagram illustrating a memory device in accordance with an embodiment of the present disclosure.

FIG. 4 is a diagram illustrating a memory die in accordance with an embodiment of the present disclosure.

FIG. 5 is a diagram illustrating a DQS calibration operation in accordance with an embodiment of the present disclosure.

FIG. 6 is a diagram illustrating a DQS calibration operation in accordance with an embodiment of the present disclosure.

FIG. 7 is a diagram illustrating a DQS calibration value in accordance with an embodiment of the present disclosure.

FIG. 8 is a diagram illustrating a DQS calibration value in accordance with an embodiment of the present disclosure.

FIG. 9 is a diagram illustrating a DQS calibration value in accordance with an embodiment of the present disclosure.

FIG. 10 is a diagram illustrating a calibration table including estimated calibration values in accordance with an embodiment of the present disclosure.

FIG. 11 is a diagram illustrating a memory controller in accordance with an embodiment of the present disclosure.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and should not be construed as limited to the embodiments set forth herein.

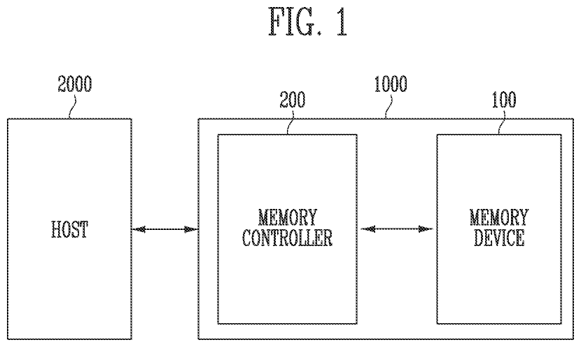

FIG. 1 is a diagram illustrating a storage device in accordance with an embodiment of the present disclosure.

Referring to FIG. 1, the storage device 1000 may include a memory device 100 and a memory controller 200.

The storage device 1000 may be a device for storing data under the control of a host 2000, such as a mobile phone, a smart phone, an MP3 player, a laptop computer, a desktop computer, a game console, a display device, a tablet PC or an in-vehicle infotainment.

The storage device 1000 may be manufactured as any of various types of storage devices according to a host interface that is a communication scheme with the host 2000. For example, the storage device 1000 may be implemented with any one of a variety of types of storage devices, such as a Solid State Drive (SSD), a Multi-Media Card (MMC), an Embedded MMC (eMMC), a Reduced Size MMC (RS-MMC), a micro-MMC (micro-MMC), a Secure Digital (SD) card, a mini-SD card, a micro-SD card, a Universal Serial Bus (USB) storage device, a Universal Flash Storage (UFS) device, a Compact Flash (CF) card, a Smart Media Card (SMC), a memory stick, and the like.

The storage device 1000 may be implemented as any of various package types. For example, the storage device 1000 may be implemented as any of various package types such as a Package-On-Package (POP), a System-In-Package (SIP), a System-On-Chip (SOC), a Multi-Chip Package (MCP), a Chip-On-Board (COB), a Wafer-level Fabricated Package (WFP), and a Wafer-level Stack Package (WSP).

The memory device 100 may store data or use stored data. The memory device 100 operates under the control of the memory controller 200. Also, the memory device 100 may include a plurality of memory dies, and each of the plurality of memory dies may include a memory cell array including a plurality of memory cells for storing data.

Each of the memory cells may be configured as a Single Level Cell (SLC) storing one data bit, a Multi-Level Cell (MLC) storing two data bits, a Triple Level Cell (TLC) storing three data bits, or a Quad Level Cell (QLC) storing four data bits.

The memory cell array may include a plurality of memory blocks. Each memory block may include a plurality of memory cells, and one memory block may include a plurality of pages. The page may be a unit for storing data in the memory device 100 or reading data stored in the memory device 100.

The memory device 100 may be implemented as a Double Data Rate Synchronous Dynamic Random Access Memory (DDR SDRAM), a Low Power Double Data Rate 4 (LPDDR4) SDRAM, a Graphics Double Data Rate (GDDR) SRAM, a Low Power DDR (LPDDR), a Rambus Dynamic Random Access Memory (RDRAM), a NAND flash memory, a vertical NAND flash memory, a NOR flash memory, a Resistive Random Access Memory (RRAM), a Phase-Change Random Access Memory (PRAM), a Magnetoresistive Random Access Memory (MRAM), a Ferroelectric Random Access Memory (FRAM), a Spin Transfer Torque Random Access Memory (STT-RAM), or the like. In this specification, for convenience of description, a case where the memory device 100 is a NAND flash memory is described.

The memory device 100 may receive a command and an address from the memory controller 200. The memory device 100 may access an area selected by the received address in the memory cell array. That the memory device 100 accesses the selected area may mean that the memory device 100 performs an operation corresponding to the received command on the selected area. For example, the memory device 100 may perform a write operation (program operation), a read operation, and an erase operation. The program operation may be an operation in which the memory device 100 records data in the area selected by the address. The read operation may mean an operation in which the memory device 100 reads data from the area selected by the address. The erase operation may mean an operation in which the memory device 100 erases data stored in the area selected by the address.

The memory controller 200 may control overall operations of the storage device 1000. Specifically, when power is applied to the storage device 1000, the memory controller 200 may execute firmware (FW). The FW may include a Host Interface Layer (HIL) which receives a request input from the host 2000 or outputs a response to the host 2000, a Flash Translation Layer (FTL) which manages an operation between an interface of the host 2000 and an interface of the memory device 100, and a Flash Interface Layer (FIL) which provides a command to the memory device 100 or receives a response from the memory device 100.

The memory controller 200 may receive data and a Logical Address (LA) from the host 2000, and translate the LA into a Physical Address (PA) representing an address of memory cells in which data included in the memory device 100 is to be stored. The LA may be a Logical Block Address (LBA), and the PA may be a Physical Block Address (PBA).

The memory controller 200 may control the memory device 100 to perform a program operation, a read operation, an erase operation, or the like in response to a request from the host 2000. In the program operation, the memory controller 200 may provide a program command, a PBA, and data to the memory device 100. In the read operation, the memory controller 200 may provide a read command and a PBA to the memory device 100. In the erase operation, the memory controller 200 may provide an erase command and a PBA to the memory device 100.

The memory controller 200 may control the memory device 100 to autonomously perform a program operation, a read operation, or an erase operation regardless of any request from the host 2000. For example, the memory controller 200 may control the memory device 100 to perform a program operation, a read operation, or an erase operation, which is used to perform a background operation such as wear leveling, garbage collection, or read reclaim.

The host 2000 may communicate with the storage device 1000, using at least one of various communication standards or interfaces, such as a Universal Serial bus (USB), a Serial AT Attachment (SATA), a High Speed InterChip (HSIC), a Small Computer System Interface (SCSI), Firewire, a Peripheral Component Interconnection (PCI), a PCI express (PCIe), a Non-Volatile Memory express (NVMe), a universal flash storage (UFS), a Secure Digital (SD), a Multi-Media Card (MMC), an embedded MMC (eMMC), a Dual In-line Memory Module (DIMM), a Registered DIMM (RDIMM), and a Load Reduced DIMM (LRDIMM).

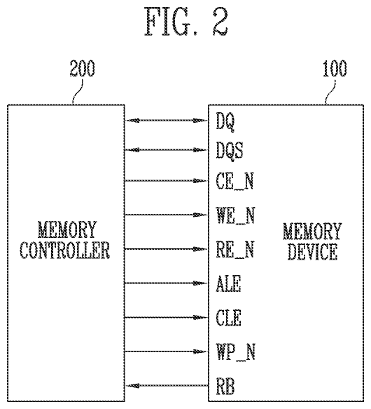

FIG. 2 is a diagram illustrating signals exchanged between the memory device and the memory controller in accordance with an embodiment of the present disclosure.

Referring FIG. 2, signals exchanged between the memory device 100 and the memory controller 200 are illustrated. Specifically, the memory device 100 may communicate with the memory controller 200 through a data (DQ) line, a data strobe (DQS) line, a chip enable (CE_N) line, a write enable (WE_N) line, a read enable (RE_N) line, an address latch enable (ALE) line, a command latch enable (CLE) line, a write protect (WP_N) line, and a ready/busy (RB) line.

The memory device 100 and the memory controller 200 may be connected to each other through a plurality of channels, and each channel may include the data (DQ) line, the data strobe (DQS) line, the chip enable (CE_N) line, the write enable (WE_N) line, the read enable (RE_N) line, the address latch enable (ALE) line, the command latch enable (CLE) line, the write protect (WP_N) line, and the ready/busy (RB) line. In addition, the memory controller 200 and a plurality of memory dies may be connected to each other through each channel. Therefore, when the memory controller 200 transmits signals through lines included in one channel, all memory dies connected to the corresponding channel or a memory die selected by the memory controller 200 among the memory dies connected to the corresponding channel may receive the signals.

The data (DQ) line may input a command, an address, and data from the memory controller 200 to the memory device 100, or output data from the memory device 100 to the memory controller 200. The data (DQ) line may be configured with 8 lines to transmit/receive 8-bit data, and each line may transmit/receive 1-bit data. However, the number of data (DQ) lines is not limited to 8, and may be extended to 16 or 32 in various embodiments.

In a write operation, the memory device 100 may receive data input through the data (DQ) line in synchronization with a data strobe (DQS) signal input through a data strobe (DQS) pad. For example, in a double data rate (DDR) mode, the memory device 100 may receive data at a rising edge and a falling edge of the data strobe (DQS) signal. In a read operation, when the memory device 100 outputs data through the data (DQ) line, the memory device 100 may output the data by synchronizing the data with the data strobe (DQS) signal. The memory device 100 may be a synchronous memory device which operates to be synchronized with the data strobe (DQS) signal.

The chip enable (CE_N) line may transfer a chip enable (CE_N) signal as a signal representing that the memory device 100 is operable. The chip enable (CE_N) signal may be selectively applied to memory devices connected to the same channel. When the chip enable (CE_N) signal falls to low, the chip enable (CE_N) signal may represent that all operations in a corresponding memory device 100 are possible. When the chip enable (CE_N) signal is high, the chip enable (CE_N) signal may represent that the corresponding memory device 100 is in a standby state.

The memory device 100 may receive a read enable (RE_N) through the read enable (RE_N) line, and receive a write enable (WE_N) signal through the write enable (WE_N) line. A read enable (RE_N) signal may be toggled when data is loaded to the memory controller 200, and the write enable (WE_N) signal may be toggled when a command and an address are loaded to the memory device 100. In an embodiment, the command and the address may be input to a selected memory device 100, when the write enable (WE_N) signal is changed from low to high, i.e., at a rising edge of the write enable (WE_N) signal. In an embodiment, the command and the address may be input to the selected memory device 100 when the write enable (WE_N) signal is changed from high to low, i.e., at a falling edge of the write enable (WE_N) signal. In an embodiment, the command and the address may be input to the selected memory device 100 when the write enable (WE_N) signal is changed from low to high and when the write enable (WE_N) signal is changed from high to low, i.e., at both the rising edge and the falling edge of the write enable (WE_N) signal.

The command latch enable (CLE) line may transfer a command latch enable (CLE) signal for inputting a command. Specifically, the memory device 100 may receive the command latch enable (CLE) signal from the memory controller 200 through the command latch enable (CLE) line. In addition, while the command is input to the memory device 100, the command latch enable (CLE) signal may become high.

The address latch enable (ALE) line may transfer an address latch enable (ALE) signal for inputting an address. Specifically, the memory device 100 may receive the address latch enable (ALE) signal from the memory controller 200 through the address latch enable (ALE) line. While the address is input to the memory device 100, the address latch enable (ALE) signal may become high.

The memory device 100 may receive a write protect (WP_N) signal through the write protect (WP_N) line. The write protect (WP_N) signal may be a signal for inactivating program and erase operations of the memory cell array.

While an operation is performed inside the memory device 100, a ready/busy (RB) signal transferred to the read/busy (RB) line may have a low state. When the ready/busy (RB) signal is in the low state, the memory device 100 may not exchange any signal with the outside. When the ready/busy (RB) signal is high, the memory device 100 may represent that the memory device 100 is in a ready state. When the memory device 100 is in the ready state, the memory device 100 may exchange a signal with the outside.

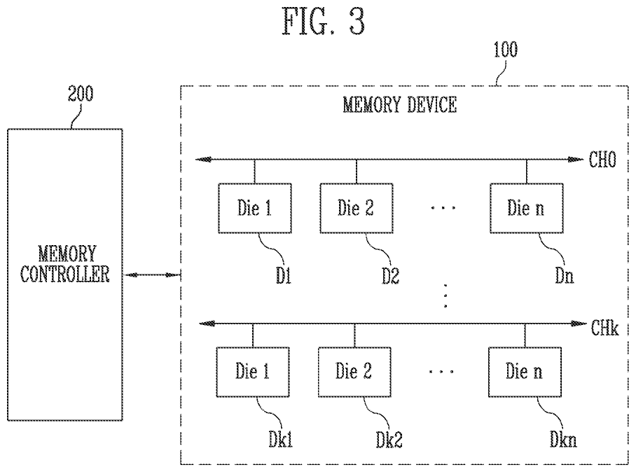

FIG. 3 is a diagram illustrating a memory device in accordance with an embodiment of the present disclosure.

Referring to FIG. 3, the memory device 100 may include a plurality of channels CH0 to CHk and a plurality of dies D1 to Dkn connected to each channel. In addition, the memory controller 200 may be connected to the memory device 100 by using the plurality of channels CH0 to CHk.

Specifically, the memory controller 200 may be connected to the plurality of channels CH0 to CHk, and be connected to the plurality of dies D1 to Dkn connected to each channel. That is, the memory controller 200 may communicate with the plurality of dies D1 to Dkn by using the plurality of channels CH0 to CHk.

The memory controller 200 may control the plurality of dies D1 to Dkn to be independently operated. Specifically, the memory controller 200 may control the plurality of dies D1 to Dkn such that a target die among the plurality of dies D1 to Dkn performs an internal operation by using at least one signal among the signals shown in FIG. 2.

For example, the memory controller 200 may control the memory device 100 such that a first die D1 connected to a zeroth channel CH0 and a first die Dk1 connected to a kth channel CHk perform a write operation or a read operation by using the write enable (WE_N) signal, the read enable (RE_N) signal, a chip enable (CE_N) signal, and the like.

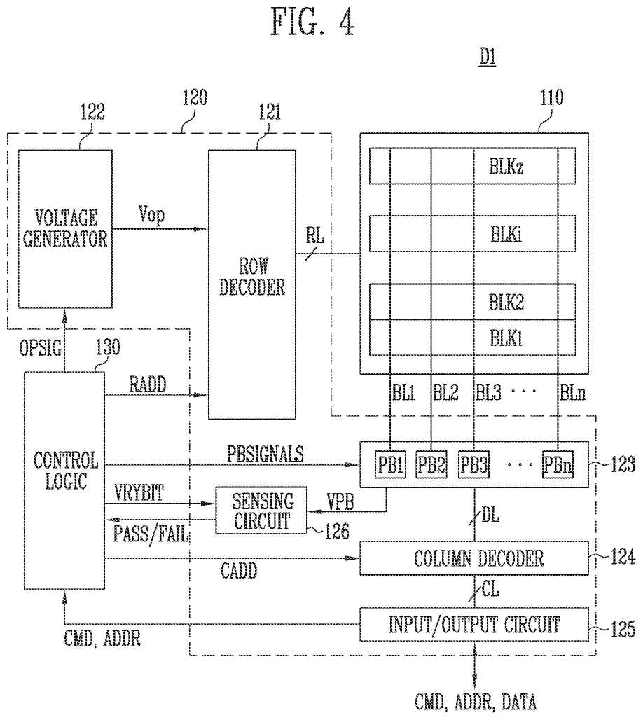

FIG. 4 is a diagram illustrating a memory die in accordance with an embodiment of the present disclosure.

The memory die D1 shown in FIG. 4 may be any die among the plurality of dies D1 to Dkn shown in FIG. 3. Also, the memory die D1 may include a memory cell array 110, a peripheral circuit 120, and a control logic 130.

The memory cell array 110 includes a plurality of memory blocks BLK1 to BLKz. The plurality of memory blocks BLK1 to BLKz are connected to a row decoder 121 through row lines RL. The row lines RL may include at least one source select line, a plurality of word lines, and at least one drain select line. The plurality of memory blocks BLK1 to BLKz are connected to a page buffer group 123 through bit lines BL1 to BLn. Each of the plurality of memory blocks BLK1 to BLKz includes a plurality of memory cells. In an embodiment, the plurality of memory cells may be nonvolatile memory cells. Memory cells connected to the same word line may be defined as one page. Therefore, one memory block may include a plurality of pages.

Each of the memory cells included in the memory cell array 110 may be configured as a Single Level Cell (SLC) storing one data bit, a Multi-Level Cell (MLC) storing two data bits, a Triple Level Cell (TLC) storing three data bits, or a Quadruple Level Cell (QLC) storing four data bits.

The peripheral circuit 120 may be configured to perform a program operation, a read operation or an erase operation on a selected area of the memory cell array 110 under the control of the control logic 130. That is, the peripheral circuit 120 may drive the memory cell array 110 under the control of the control logic 130. For example, the peripheral circuit 120 may apply various operating voltages to the row lines RL and the bit lines BL1 to BLn or discharge the applied voltages under the control of the control logic 130.

Specifically, the peripheral circuit 120 may include the row decoder 121, a voltage generator 122, the page buffer group 123, a column decoder 124, an input/output circuit 125, and a sensing circuit 126.

The row decoder 121 may be connected to the memory cell array 110 through the row lines RL. The row lines RL may include at least one source select line, a plurality of word lines, and at least one drain select line. In an embodiment, the word lines may include normal word lines and dummy word lines. In an embodiment, the row lines RL may further include a pipe select line.

The row decoder 121 may operate under the control of the control logic 130. The row decoder 121 may receive a row address RADD from the control logic 130. Specifically, the row decoder 121 may decode the row address RADD. The row decoder 121 may select at least one memory block among the memory blocks BLK1 to BLKz according to the decoded address. Also, the row decoder 121 may select at least one word line of the selected memory block to apply voltages generated by the voltage generator 122 to the at least one word line WL according the decoded address.

For example, in a program operation, the row decoder 121 may apply a program voltage to the selected word line, and apply a program pass voltage having a level lower than that of the program voltage to unselected word lines. In a program verify operation, the row decoder 121 may apply a verify voltage to the selected word line, and apply a verify pass voltage higher than the verify voltage to the unselected word lines. In a read operation, the row decoder 121 may apply a read voltage to the selected word line, and apply a read pass voltage higher than the read voltage.

In an embodiment, an erase operation of the memory device 100 may be performed in a memory block unit. In the erase operation, the row decoder 121 may select one memory block according to the decoded address. In the erase operation, the row decoder 121 may apply a ground voltage to word lines connected to the selected memory block.

The voltage generator 122 may operate under the control of the control logic 130. Specifically, the voltage generator 122 may generate a plurality of voltages by using an external power voltage supplied to the memory device 100 under the control of the control logic 130. For example, the voltage generator 122 may generate a program voltage, a verify voltage, a pass voltage, a read voltage, an erase voltage, and the like under the control of the control logic 130. That is, the voltage generator 122 may generate various operating voltages Vop used in program, read, and erase operations in response to an operation signal OPSIG.

In an embodiment, the voltage generator 122 may generate an internal power voltage by regulating the external power voltage. The internal power voltage generated by the voltage generator 122 may be used as an operation voltage of the memory cell array 110.

In an embodiment, the voltage generator 122 may generate a plurality of voltages by using the external power voltage or the internal power voltage. For example, the voltage generator 122 may include a plurality of pumping capacitors for receiving the internal power voltage, and generate the plurality of voltages by selectively activating the plurality of pumping capacitors under the control of the control logic 130. In addition, the plurality of generated voltages may be supplied to the memory cell array 110 by the row decoder 121.

The page buffer group 123 may include first to nth page buffers PB1 to PBn. The first to nth page buffers PB1 to PBn may be connected to the memory cell array 110 respectively through first to nth bit lines BL1 to BLn. Also, the first to nth bit lines BL1 to BLn may operate under the control of the control logic 130. Specifically, the first to nth bit lines BL1 to BLn may operate in response to page buffer control signals PBSIGNALS. For example, the first to nth page buffers PB1 to PBn may temporarily store data received through the first to nth bit lines BL1 to BLn, or sense a voltage or current of the bit lines BL1 to BLn in a read or verify operation.

Specifically, in a program operation, the first to nth page buffers PB1 to PBn may transfer data DATA received through the input/output circuit 125 to selected memory cells through the first to nth bit lines BL1 to BLn, when a program voltage is applied to a selected word line. Memory cells of a selected page may be programmed according to the transferred data DATA. A memory cell connected to a bit line to which a program allow voltage (e.g., a ground voltage) is applied may have an increased threshold voltage. A threshold voltage with respect to a memory cell connected to a bit line to which a program inhibit voltage (e.g., a power voltage) is applied may be maintained.

In a program verify operation, the first to nth page buffers PB1 to PBn may read page data from the selected memory cells through the first to nth bit lines BL1 to BLn.

In a read operation, the first to nth page buffers PB1 to PBn may read data DATA from the memory cells of the selected page through the first to nth bit lines BL1 to BLn, and output the read data DATA to the input/output circuit 125 under the control of the column decoder 124.

In an erase operation, the first to nth page buffers PB1 to PBn may float the first to nth bit lines BL1 to BLn.

The column decoder 124 may communicate data between the input/output circuit 125 and the page buffer group 123 in response to a column address CADD. For example, the column decoder 124 may communicate data with the first to nth page buffers PB1 to PBn through data lines DL, or communicate data with the input/output circuit 125 through column lines CL.

The input/output circuit 125 may transfer a command CMD and an address ADDR, which are received from the memory controller 200, to the control logic 130, or exchange data DATA with the column decoder 124.

In a read operation or verify operation, the sensing circuit 126 may generate a reference current in response to an allow bit VRYBIT signal, and output a pass PASS or a fail signal FAIL by comparing a sensing voltage VPB received from the page buffer group 123 and a reference voltage generated by the reference current.

The control logic 130 may control the peripheral circuit 120 by outputting the operation signal OPSIG, the row address RADD, the page buffer control signals PBSIGNALS, and the allow bit VRYBIT in response to the command CMD and the address ADDR.

Also, the control logic 130 may determine whether the verify operation has passed or failed in response to the pass or fail signal PASS or FAIL. The control logic 130 may determine a program state of a memory cell in response to the pass or fail signal PASS or FAIL. For example, when the memory cell operates as a Triple Level Cell (TLC), the control logic 130 may determine whether the program state of the memory cell is an erase state E or one of first to seventh program states P1 to P7.

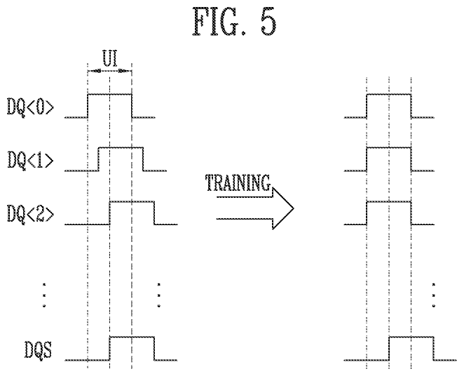

FIG. 5 is a diagram illustrating a DQS calibration operation in accordance with an embodiment of the present disclosure.

Referring to FIG. 5, a DQS calibration operation between the memory device 100 and the memory controller 200 is illustrated. The DQS calibration operation may be an operation of compensating for a skew between data and a data strobe (DQS) signal by adjusting a delay of the data strobe (DQS) signal when the memory device 100 and the memory controller 200 transmit/receive the data by using the data strobe (DQS) signal.

The memory device 100 may include a latch circuit for latching data according to the data strobe (DQS) signal. A data pad DQ_P and a data strobe (DQS) pad, which are included in the memory device 100, are located at different distances from the latch circuit, and all paths through which a signal passes from data strobe (DQS) lines and a data (DQ) line to the latch circuit are physically different from each other. Although a signal is transmitted from each data line in synchronization with the data strobe (DQS) signal, a phase difference (i.e., a skew) between the signals transmitted from the data lines may occur due to a difference between the physical phases. Each data (e.g., DQ<7:0>) transmitted/received through each channel may include a unit interval UI defined by a rising edge and a falling edge. The unit interval UI may be defined as a valid window, and the DQS calibration operation may be a training operation of adjusting a delay amount of each path (or compensating for a timing) such that a rising edge of the data strobe (DQS) signal is located at the center of the valid window transmitted to the data (DQ) line.

In accordance with an embodiment of the present disclosure, the DQS calibration operation may include a write training operation and a read training operation for each of a plurality of channels. That is, the memory controller 200 may calculate a DQS calibration value in a write operation through the write training operation for each channel and calculate a DQS calibration value in a read operation through the read training operation for each channel.

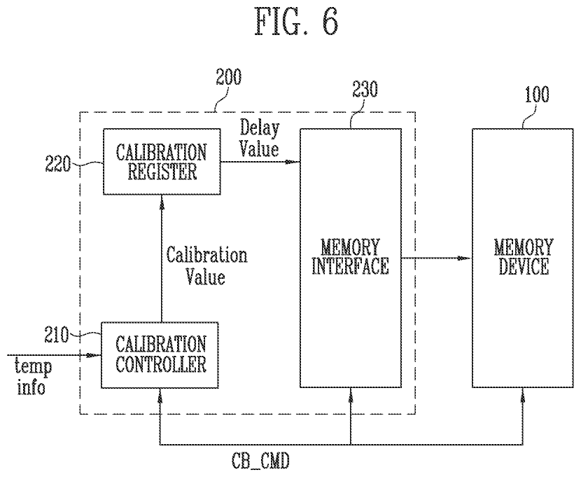

FIG. 6 is a diagram illustrating a DQS calibration operation in accordance with an embodiment of the present disclosure.

Referring to FIG. 6, a diagram is illustrated, in which a DQS calibration operation is performed between the memory controller 200 including a calibration controller 210, a calibration register 220, and a memory interface 230, and the memory device 100.

The calibration controller 210 may control the memory device 100 and the memory controller 200 to perform a DQS calibration operation. The DQS calibration operation may be an operation of measuring a DQS calibration value representing an amount of adjusted delay of a data strobe (DQS) signal when the memory device 100 and the memory controller 200 transmit/receive data by using the data strobe (DQS) signal. The data strobe (DQS) signal may be a signal used in a NAND flash interface (NAND I/F) while data is transmitted/received to/from the memory device 100.

In an embodiment, the DQS calibration value may represent an amount of adjusted delay of the data strobe (DQS) signal in units of nanoseconds. In an embodiment, the DQS calibration value may be measured for each channel connected to a plurality of memory dies. The calibration controller 210 may measure a DQS calibration value for each memory die, that is, one DQS calibration value is measured per a channel to which a plurality of memory dies are connected.

The calibration controller 210 may receive temperature information from a temperature sensor or a device for measuring a temperature of the storage device 1000. Also, the calibration controller 210 may measure DQS calibration values at a plurality of temperatures. In accordance with an embodiment, the calibration controller 210 may measure DQS calibration values at three temperatures or more. For example, the calibration controller 210 may measure a first calibration value with respect to the data strobe (DQS) signal at a first temperature, measure a second calibration value with respect to the data strobe (DQS) signal at a second temperature, and measure a third calibration value with respect to the data strobe (DQS) signal at a third temperature.

In an embodiment, the calibration controller 210 may measure a DQS calibration value for each operation mode. For example, the calibration controller 210 may measure a DQS calibration value corresponding to a write operation of storing data in the memory device 100, and measure a DQS calibration value corresponding to a read operation of reading data from the memory device 100.

In accordance with an embodiment of the present disclosure, the calibration controller 210 may perform a DQS calibration operation while a booting operation of executing an operating system (OS) for executing a command from the host 2000 is performed after external power is input. That is, the calibration controller 210 may perform a DQS calibration operation of measuring DQS calibration values respectively corresponding to at least three temperatures, at the at least three temperatures while a booting operation of the storage device 1000 is performed.

In accordance with an embodiment of the present disclosure, the calibration controller 210 may perform a DQS calibration operation in an idle state in which any command is not received from the host 2000 for a certain time or more. That is, the calibration controller 210 may perform, in the idle state, a DQS calibration operation of measuring DQS calibration values respectively corresponding to at least three temperatures as the at least three temperatures.

The calibration register 220 may receive, from the calibration controller 210, temperature information for a plurality of temperatures and DQS calibration values corresponding to the plurality of temperatures. Also, the calibration register 220 may generate an equation for the temperature information and the DQS calibration values. For example, the calibration register 220 may receive, from the calibration controller 210, information for first to third temperatures and first to third calibration values at the first to third temperatures, and generate an equation between a temperature and a DQS calibration value, based on the information for the first to third temperatures and the first to third calibration values. The equation may include a linear equation in which the DQS calibration value is linearly changed as the temperature is changed or a non-linear equation in which the DQS calibration value is non-linearly changed as the temperature is changed.

Also, the calibration register 220 may store a calibration table, based on the generated equation. Specifically, the calibration register 220 may calculate, based on the equation, an estimated calibration value determined according to a temperature. Also, the calibration register 220 may calculate an estimated calibration value with respect to the entire operation temperature section including the first to third temperatures. The calibration register 220 may store, in the calibration table, an operation temperature section and an estimated calibration value corresponding to the operation temperature section.

The memory interface 230 may communicate with the memory device 100, based on the calibration table. Specifically, the memory interface 230 may communicate with the memory device 100 by using a data strobe (DQS) signal to which the estimated calibration value stored in the calibration table is applied. For example, the memory interface 230 may transmit, to the memory device 100, a data strobe (DQS) signal to which the estimated calibration value is applied, and receive data used for a write operation, based on the data strobe (DQS) signal to which the estimated calibration value is applied.

In accordance with an embodiment of the present disclosure, the calibration controller 210 may measure a DQS calibration value for each predetermined cycle to update the calibration table. Specifically, the calibration controller 210 may measure a current DQS calibration value with respect to the data strobe (DQS) signal at a current temperature of the storage device 1000 for each predetermined cycle. In addition, the calibration register 220 may update the calibration table according to a result obtained by comparing the current DQS calibration value measured at the current temperature of the storage device 1000 with the estimated calibration value stored in the calibration table. Specifically, when a difference between the current DQS calibration value at the current temperature of the storage device 1000 and the estimated calibration value is greater than or equal to a predetermined threshold value, the calibration register 220 may update the estimated calibration value stored in the calibration table as the current DQS calibration value measured at the current temperature of the storage device 1000.

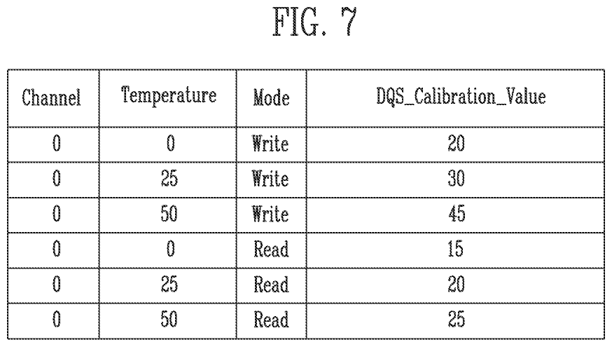

FIGS. 7 to 9 are diagrams illustrating a DQS calibration value in accordance with an embodiment of the present disclosure.

Referring to FIG. 7, a result obtained by performing, by the memory controller 200, a DQS calibration operation on a specific channel is illustrated. Specifically, the memory controller 200 may perform a DQS calibration operation for each channel, and the DQS calibration operation may separately determine a calibration value used for a write operation and a calibration value used for a read operation. In addition, a DQS calibration value may include a first calibration value determined at a first temperature, a second calibration value determined at a second temperature, and a third calibration value determined at a third temperature. In accordance with an embodiment of the present disclosure, an equation between a temperature and a calibration value may be generated according to calibration values determined at three temperatures or more.

For example, the memory controller 200 may perform a DQS calibration operation on a zeroth channel. In accordance with an embodiment, the DQS calibration operation may be performed at three temperatures or more. For example, the memory controller 200 may calculate each of DQS calibration values with respect to the write operation and the read operation at 0° C. as the first temperature, 25° C. as the second temperature, and 50° C. as the third temperature. The memory controller 200 may calculate, as 20 ns, a DQS calibration value with respect to a plurality of memory dies connected to the zeroth channel at 0° C. in the write operation. The memory controller 200 may calculate, as 30 ns, the DQS calibration value with respect to the plurality of memory dies connected to the zeroth channel at 25° C. in the write operation. The memory controller 200 may calculate, as 45 ns, the DQS calibration value with respect to the plurality of memory dies connected to the zeroth channel at 50° C. in the write operation.

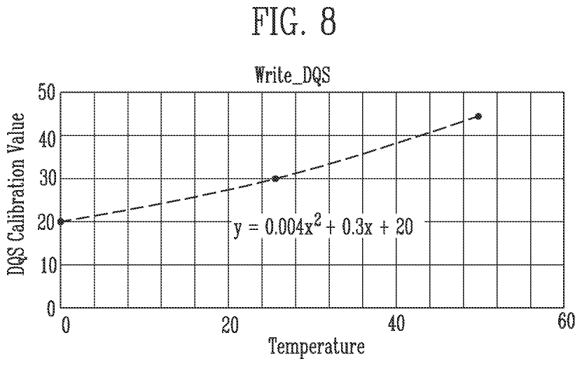

Referring to FIG. 8, the memory controller 200 may generate an equation, based on temperature information for a plurality of temperatures and DQS calibration values corresponding to the plurality of temperatures.

For example, the memory controller 200 may generate a non-linear equation by using 20 ns as the DQS calibration value calculated at 0° C. in the write operation, 30 ns as the DQS calibration value calculated at 25° C. In the write operation, and 45 ns as the DQS calibration value calculated at 50° C. in the write operation. That is, the memory controller 200 may generate a non-linear equation to constitute a secondary function in which an x axis is temperature and a y axis is DQS calibration value.

Referring back to FIG. 7, the memory controller 200 may calculate as 15 ns, a DQS calibration value with respect to the plurality of memory dies connected to the zeroth channel at 0° C. in the read operation. The memory controller 200 may calculate as 20 ns, a DQS calibration value with respect to the plurality of memory dies connected to the zeroth channel at 25° C. in the read operation. The memory controller 200 may calculate as ns, a DQS calibration value with respect to the plurality of memory dies connected to the zeroth channel at 50° C. in the read operation.

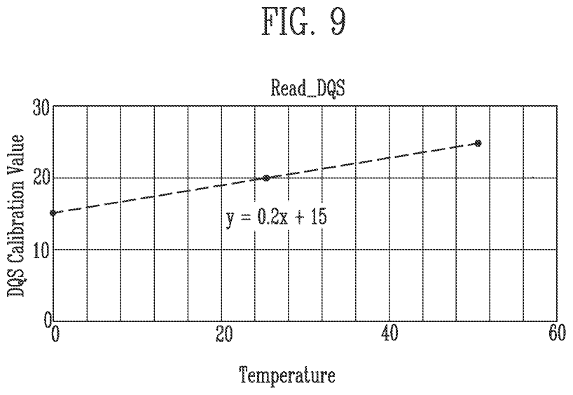

Referring to FIG. 9, the memory controller 200 may generate a linear equation by using 15 ns as the DQS calibration value calculated at 0° C. in the read operation, 20 ns as the DQS calibration value calculated at 25° C. in the read operation, and 25 ns as the DQS calibration value calculated at 50° C. in the read operation. That is, the memory controller may generate a non-linear equation to constitute a primary function in which an x axis is temperature and a y axis is DQS calibration value.

Meanwhile, the equations and the graphs, which are shown in FIGS. 8 and 9, are used to describe the non-linear equation or the linear equation, which is generated in the write operation or the read operation. A linear equation may be generated by using DQS calibration values calculated at the first to third temperatures in the write operation, or a non-linear equation may be generated by using DQS calibration values calculated at the first to third temperatures in the read operation.

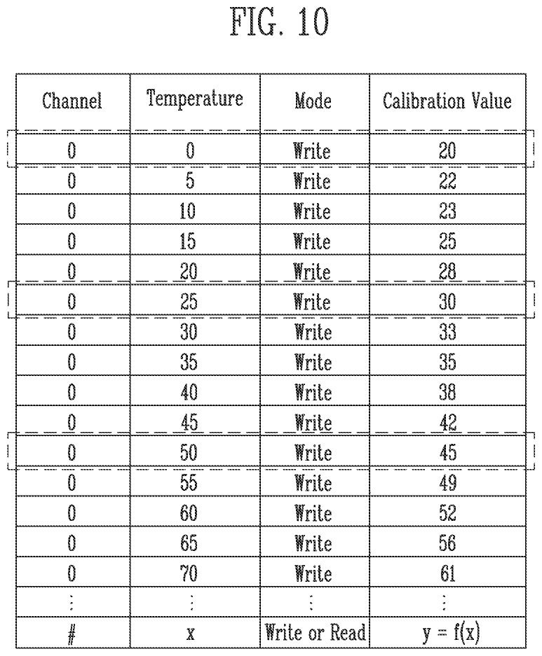

FIG. 10 is a diagram illustrating a calibration table including estimated calibration values in accordance with an embodiment of the present disclosure.

Referring to FIG. 10, the memory controller 200 may store a calibration table including an estimated calibration value for each channel. Specifically, the memory controller 200 may generate an equation by using DQS calibration values measured at a plurality of temperatures. Also, the memory controller 200 may generate estimated calibration values according to temperatures by using the generated equation.

For example, the memory controller 200 may generate a non-linear equation by using 20 ns as a DQS calibration value calculated at 0° C. in the write operation, 30 ns as a DQS calibration value calculated at 25° C. in the write operation, and 45 ns as a DQS calibration value calculated at 50° C. in the write operation. Also, the memory controller 200 may generate a calibration table including an estimated calibration value with respect to an operation temperature section including 0° C. to 50° C.

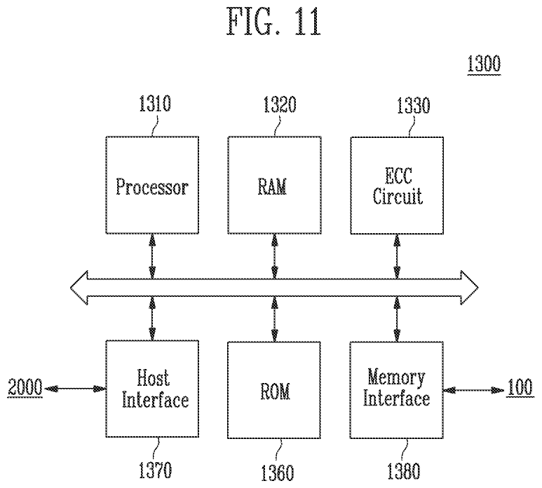

FIG. 11 is a diagram illustrating a memory controller in accordance with an embodiment of the present disclosure.

Referring to FIG. 11, the memory controller 1300 may include a processor 1310, a RAM 1320, and an ECC circuit 1330, a ROM 1360, a host interface 1370, and a memory interface 1380. The memory controller 1300 shown in FIG. 11 may be an embodiment of the memory controller 200 shown in FIGS. 1 to 3 and 6.

The processor 1310 may communicate with the host 2000 by using the host interface 1370, and perform a logical operation to control an operation of the memory controller 1300. For example, the processor 1310 may load a program command, a data file, a data structure, etc., based on a request received from the host 2000 or an external device, and perform various operations or generate a command and an address. For example, the processor 1310 may generate various commands necessary for a program operation, a read operation, an erase operation, a suspend operation, and a parameter setting operation.

Also, the processor 1310 may perform a function of a Flash Translation Layer (FTL). The processor 250 may translate a Logical Block Address (LBA) provided by the host 2000 into a Physical Block Address (PBA) through the FTL. The FTL may receive an LBA input by using a mapping table, to translate the LBA into a PBA. Several address mapping methods of the FTL exist according to mapping units. A representative address mapping method includes a page mapping method, a block mapping method, and a hybrid mapping method.

Also, the processor 1310 may generate a command without any request from the host 2000. For example, the processor 1310 may generate a command for background operations such as operations for wear leveling of the memory device 100 and operations for garbage collection of the memory device 100.

The RAM 1320 may be used as a buffer memory, a working memory, or a cache memory of the processor 1310. Also, the RAM 1320 may store codes and commands, which the processor 1310 executes. The RAM 1320 may store data processed by the processor 1310. Also, the RAM 1320 may be implemented with, for example a Static RAM (SRAM) or a Dynamic RAM (DRAM).

The ECC circuit 1330 may detect an error in a program operation or a read operation, and correct the detected error. Specifically, the ECC circuit 1330 may perform an error correction operation according to an Error Correction Code (ECC). Also, the ECC circuit 1330 may perform ECC encoding, based on data to be written to the memory device 100. The data on which the ECC encoding is performed may be transferred to the memory device 100 through the memory interface 1380. Also, the ECC circuit 1330 may perform ECC decoding on data received from the memory device 100 through the memory interface 1380.

The ROM 1360 may be used as a storage unit for storing various information necessary for an operation of the memory controller 1300. Specifically, the ROM 1360 may include a map table. Physical-to-logical address information and logical-to-physical address information may be stored in the map table. Also, the ROM 1360 may be controlled by the processor 1310.

The host interface 1370 may include a protocol for exchanging data between the host 2000 and the memory controller 1300. Specifically, the host interface 1370 may communicate with the host 2000 through at least one of various communication standards or interfaces such as a Universal Serial Bus (USB) protocol, a Multi-Media Card (MMC) protocol, a Peripheral Component Interconnection (PCI) protocol, a PCI-Express (PCI-e or PCIe) protocol, an Advanced Technology Attachment (ATA) protocol, a Serial-ATA protocol, a Parallel-ATA protocol, a Small Computer System Interface (SCSI) protocol, an Enhanced Small Disk Interface (ESDI) protocol, an Integrated Drive Electronics (IDE) protocol, and a private protocol.

The memory interface 1380 may communicate with the memory device 100 by using a communication protocol under the control of the processor 1310. Specifically, the memory interface 1380 may communicate a command, an address, and data with the memory device 100 through a channel. For example, the memory interface 1380 may include a NAND flash interface.

In accordance with the present disclosure, there can be provided a storage device for supporting an improved calibration operation on a data strobe signal and an operating method of the storage device.

While the present disclosure has been shown and described with reference to certain embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all operations may be selectively performed or part of the operations may be omitted. In each embodiment, the operations are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Furthermore, the embodiments of the present disclosure have been described in the drawings and specification. Although specific terminologies are used here, the terminologies are only to describe the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein and the following claims. Furthermore, the embodiments may be combined to form additional embodiments.

What is claimed is:

1. A storage device comprising:
a memory device including a plurality of memory dies;
a calibration controller configured to perform a calibration operation of measuring first to third calibration values with respect to a data strobe signal at first to third temperatures of the storage device, respectively;
a calibration register configured to generate an equation between a temperature and a calibration value based on the first to third calibration values and the first to third temperatures, and to store a calibration table based on the equation; and
a memory interface configured to communicate with the memory device based on the calibration table.

2. The storage device of claim 1, wherein each of the first to third calibration values corresponds to an amount of adjusted delay of the data strobe signal transferred through a channel connected between the memory interface and the plurality of memory dies.

3. The storage device of claim 1, wherein the calibration controller performs the calibration operation during a booting operation of the storage device.

4. The storage device of claim 1, wherein the calibration controller performs the calibration operation in an idle state of the storage device.

5. The storage device of claim 1, wherein the data strobe signal is a signal used in a NAND flash interface while data is transmitted/received to/from the memory device.

6. The storage device of claim 1, wherein the calibration register generates a linear equation or a non-linear equation, based on the first to third calibration values and the first to third temperatures.

7. The storage device of claim 1, wherein the calibration controller is further configured to periodically measure a current calibration value with respect to the data strobe signal at a current temperature of the storage device.

8. The storage device of claim 7, wherein the calibration register is further configured to update the calibration table according to a result obtained by comparing the current calibration value with an estimated calibration value stored in the calibration table and corresponding to the current temperature.

9. The storage device of claim 8, wherein the calibration register updates the calibration table when a difference between the current calibration value and the estimated calibration value is greater than or equal to a predetermined threshold value.

10. The storage device of claim 1, wherein:
the calibration register is further configured to calculate, based on the equation, an estimated calibration value at an operation temperature section including the first to third temperatures, and
the calibration register stores the calibration table including the operation temperature section and the estimated calibration value corresponding to the operation temperature section.

11. The storage device of claim 1, wherein each of the first to third calibration values corresponds to a write operation or a read operation of the memory device.

12. A method of operating a storage device, the method comprising:
performing a calibration operation of measuring first to third calibration values with respect to a data strobe signal at first to third temperatures of the storage device, respectively;
generating an equation between a temperature and a calibration value, based on the first to third calibration values and the first to third temperatures;
storing a calibration table based on the equation; and
communicating with a memory device, based on the calibration table.

13. The method of claim 12, wherein each of the first to third calibration values corresponds to an amount of adjusted delay of the data strobe signal transferred through a channel connected between a memory controller and a memory die.

14. The method of claim 12, wherein the calibration operation is performed during a booting operation of the storage device.

15. The method of claim 12, wherein the calibration operation is performed in an idle state of the storage device.

16. The method of claim 12, further comprising periodically measuring a current calibration value with respect to the data strobe signal at a current operation temperature of the storage device.

17. The method of claim 16, further comprising updating the calibration table according to a result obtained by comparing the current calibration value with an estimated calibration value stored in the calibration table and corresponding to the current temperature.

18. The method of claim 17, wherein the calibration table is updated when a difference between the current calibration value and the estimated calibration value is greater than or equal to a predetermined threshold value.

19. The method of claim 12,
further comprising calculating, based on the equation, an estimated calibration value at an operation temperature section including the first to third temperatures, and
wherein the storing the calibration table includes storing the calibration table including the operation temperature section and the estimated calibration value corresponding to the operation temperature section.

20. A storage device comprising:
a memory controller configured to provide a data strobe signal; and
a memory device configured to receive and transmit data from and to the memory controller based on the data strobe signal,
wherein the memory controller is configured to perform a DQS calibration operation by:
measuring a plurality of data strobe signal (DQS) calibration values at multiple temperatures;
determining an estimation model indicating the relationship between DQS calibration values and temperatures based on the measured the DQS calibration values and the measured multiple temperatures;
measuring a DQS calibration value at an operation temperature of the storage device;
determining a DQS calibration estimation value corresponding to the operation temperature using the estimation model, the DQS calibration estimation value for calibrating the data strobe signal;
comparing the DQS calibration value measured at the operation temperature with DQS calibration estimation value; and
updating the estimation model based on the comparison result.
